(19) United States
(12) Patent Application Publication
(10) Pub. No.: US 2007/0166953 A1
(43) Pub. Date: Jul. 19, 2007

(54) Semiconductor device and method of fabricating the same

(75) Inventor: Hyung Sun Yun, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/645,496

(22) Filed: Dec. 27, 2006

(30) Foreign Application Priority Data
Dec. 29, 2005 (KR) 10-2005-0133890

(51) Int. Cl. H01L 21/76; H01L 29/00

(52) U.S. Cl. 438/429; 438/427; 257/506

(57) ABSTRACT

A method of fabricating a transistor of a semiconductor device comprises forming first and second trenches for gates in a substrate; forming a liner layer on innerwalls of the first and second trenches; forming first and second epitaxial gate electrodes by performing an epitaxial growth on the first and second trenches comprising the liner layers therein; forming isolation structures in the substrate, wherein the isolation structures contact the first and second epitaxial gate electrodes, respectively; forming a gate insulation layer and a gate electrode over a region of the substrate between the first and second epitaxial gate electrodes; and forming source and drain regions in the substrate disposed in respective edge regions of the gate electrode and overlapping the gate electrode.

### RELATED APPLICATIONS

The present application is related to, and claims priority from, Korean Patent Application No. 10-2005-0133890, filed Dec. 29, 2005, which is hereby incorporated by reference herein in its entirety.

### FIELD OF THE INVENTION

The present invention relates to a semiconductor device and a method of fabricating the same, and more particularly, to a transistor of a semiconductor device and a method for fabricating the same.

### BACKGROUND OF THE INVENTION

A metal-oxide semiconductor (MOS) transistor is a type of field effect transistors (FETs), and is formed in a structure including source and drain regions formed in a substrate, a gate oxide layer and a gate both being formed over the substrate provided with the source and drain regions. A MOS transistor having lightly doped drain (LDD) regions in inner side portions of the source and drain regions is mainly used.

Depending on a channel type, such a MOS transistor can be classified into an N-type channel MOS transistor or a P-type channel MOS transistor. A complementary metal-oxide semiconductor (CMOS) transistor refers to a transistor obtained when both the N-type channel MOS transistor and the P-type channel MOS transistor are formed on one substrate.

With reference to FIG. 1, a typical MOS transistor structure will be described.

In the typical MOS transistor, an isolation structure 14 is defined, and an initial oxide layer is grown on a P-type or N-type single crystal substrate 10. A well 12, filled with P-type impurities or N-type impurities, is formed in the substrate 10. A gate oxide layer 16a is formed on a boundary region of the well 12 in the substrate 10. A polysilicon layer is then formed on the gate oxide layer 16a and patterned to form a gate electrode 16b using lithography. Lightly doped impurity ions are implanted onto the substrate 10 using the gate electrode 16b as a mask, and heat treated to form lightly doped diffusion regions 18a. Spacers 17 are formed on sidewalls of the gate electrode 16b. Heavily doped impurity ions are implanted onto the substrate 10 using the spacers 17 as a resist, and heat-treated to form heavily doped diffusion regions 18b.

As for operation of the typical MOS transistor including the lightly and heavily doped diffusion regions 18a and 18b (i.e., source and drain regions) and the gate electrode 16b, when a voltage is applied to the gate electrode 16b, a region where the gate oxide layer 16a and the substrate 10 contact each other between the lightly doped diffusion regions 18a and between the heavily doped diffusion regions 18b becomes a channel region. When a voltage is applied to a drain electrode, current flows through the channel region.

However, in the typical MOS transistor as illustrated in FIG. 1, since current flows through the channel region contacting the gate oxide layer 16a, which is formed beneath the gate electrode 16b, the typical MOS transistor has weak current drivability in comparison with a typical bipolar junction transistor.

### SUMMARY OF THE INVENTION

It is, therefore, an object of the present invention to provide a transistor of a semiconductor device improved in current drivability, and a method of fabricating the same.

In accordance with an aspect of the present invention, there is provided a method of fabricating a transistor of a semiconductor device, the method comprising:

forming first and second trenches for gates in a substrate, wherein the trenches are spaced apart from each other a predetermined distance;

forming a liner layer on innerwalls of the first and second trenches;

performing a selective epitaxial growth on the first and second trenches comprising the liner layers therein to form first and second epitaxial gate electrodes;

forming isolation structures in the substrate, wherein the isolation structures contact the first and second epitaxial gate electrodes, respectively;

forming a gate insulation layer and a gate electrode over a region of the substrate between the first and second epitaxial gate electrodes; and

forming source and drain regions in the substrate disposed in respective edge regions of the gate electrode to overlap with the gate electrode.

In accordance with another aspect of the present invention, there is provided a transistor of a semiconductor device, the transistor comprising:

isolation structures formed in an isolation region of a substrate;

a gate insulation layer formed over an active region of the substrate;

a gate electrode formed over the gate insulation layer;

first and second epitaxial gate electrodes formed in the substrate and spaced apart from each other and comprising the gate electrode disposed on the substrate therebetween, wherein the gate electrode overlaps the first epitaxial gate electrode and the second epitaxial gate electrode; and

source and drain regions formed in the substrate disposed in respective edge regions of the gate electrode and overlapping the gate electrode.

### BRIEF DESCRIPTION OF THE DRAWINGS

The above and other objects and features of the present invention will become apparent from the following description of preferred embodiments given in conjunction with the accompanying drawings, in which:

FIG. 1 illustrates a sectional view of a typical MOS transistor;

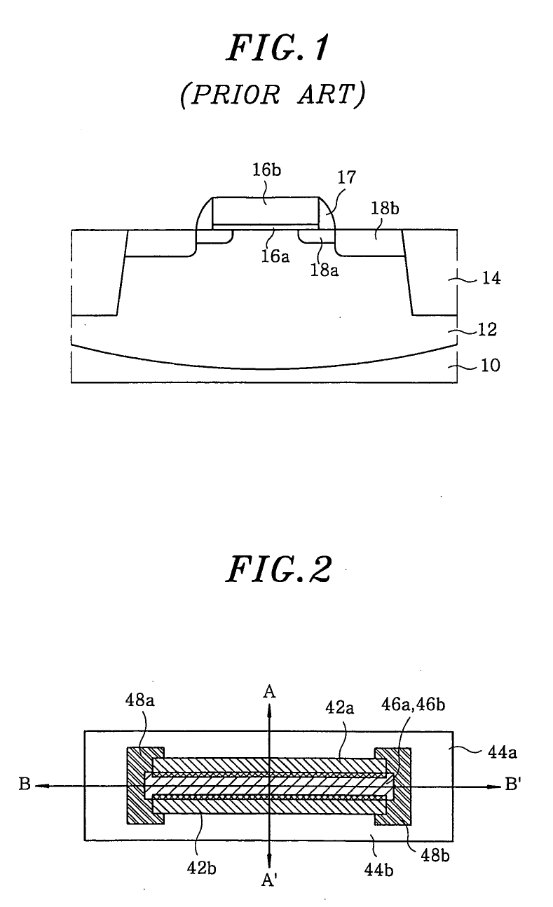

FIG. 2 illustrates a layout of a transistor in accordance with an embodiment of the present invention; and

FIGS. 3 to 8 illustrate sectional views to describe a method of fabricating a transistor of a semiconductor device in accordance with an embodiment of the present invention.

### DETAILED DESCRIPTION

Hereinafter, some embodiments of the present invention will be described in detail with reference to the accompanying drawings, so that they can be readily implemented by those skilled in the art.

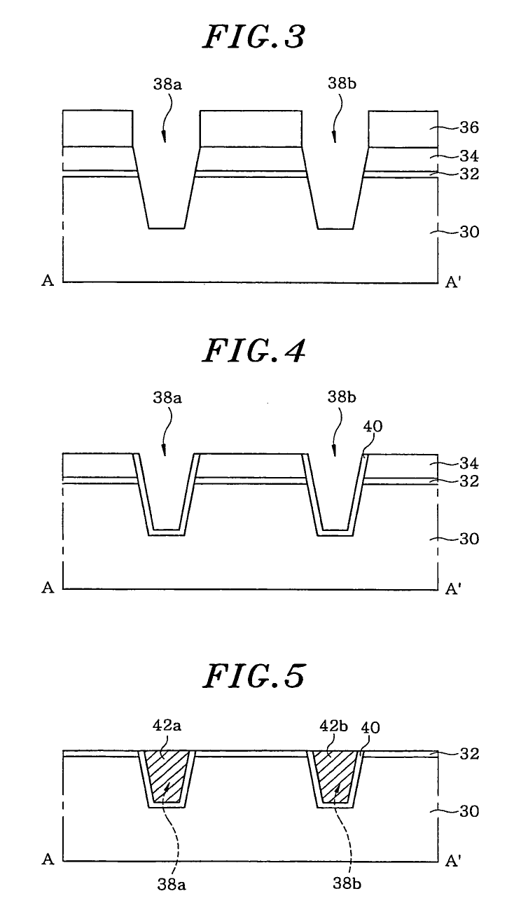

Referring to FIG. 2, there is illustrated a layout of a transistor fabricated in accordance with an embodiment of the present invention.

The transistor in accordance with the embodiment of the present invention includes first and second isolation structures 44a and 44b, a patterned gate insulation layer 46a, a gate electrode 46b, first and second epitaxial gate electrodes 42a and 42b, and source and drain regions 48a and 48b. The patterned gate insulation layer 46a comprises an oxide-based material. The first and second isolation structures 44a and 44b are formed in an isolation region of a substrate. The patterned insulation layer 46a and the gate electrode 46b are formed in an active region of the substrate. The first and second epitaxial gate electrodes 42a and 42b are spaced apart from each other in the substrate such that the gate electrode 46b is disposed on the substrate between the first and second epitaxial gate electrodes 42a and 42b. The source and drain regions 48a and 48b are formed in the substrate to overlap with respective edge portions of the gate electrode 46b.

The first and second epitaxial gate electrodes 42a and 42b and the gate electrode 46b that are formed between the source region 48a and the drain region 48b function as a channel region when a certain voltage is applied. Thus, various control methods of driving current can exist depending on a method of applying a voltage to each of the above mentioned gates. As a result, current drivability of the transistor is improved.

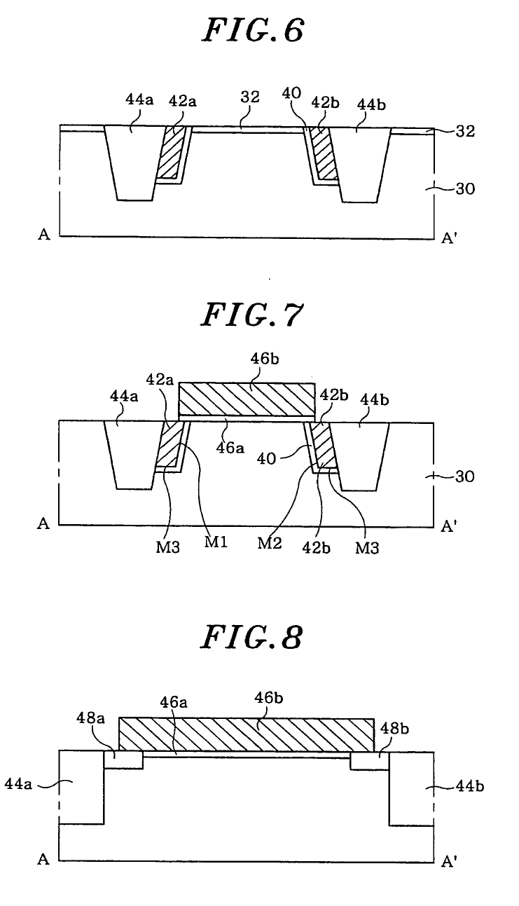

FIGS. 3 to 8 illustrate sectional views to describe a method of fabricating a transistor in accordance with an embodiment of the present invention. It should be noted that like reference numerals denote like elements described in FIG. 2.

FIGS. 3 to 7 sequentially illustrate sectional views taken along a line A-A′ shown in FIG. 2, and FIG. 8 illustrates a sectional view taken along a line B-B′ shown in FIG. 2 after performing a process illustrated in FIG. 7.

Referring to FIG. 3, a first pad layer 32 and a second pad layer 34 are sequentially formed over a substrate 30. The first pad layer 32 and the second pad layer 34 include an oxide-base material and a nitride-based material, respectively. A mask 36 for forming a trench is formed over the second pad layer 34, and a photolithography process is performed to pattern the second pad layer 34, the first pad layer 32 and the substrate 30 to a predetermined depth. As a result of this patterning, first and second trenches 38a and 38b for use in gates are formed spaced apart from each other.

Referring to FIG. 4, the mask 36 is removed, and a liner layer 40 is formed on innerwalls of the first and second trenches 38a and 38b. The liner layer 40 comprises an oxide-based material.

Referring to FIG. 5, the second pad layer 34 is removed. A selective epitaxial growth (SEG) method is performed on the first pad layer 32, so that epitaxial layers are formed over respective first and second trenches 38a and 38b where the liner layer 40 is formed. As a result of the SEG method, first and second epitaxial gate electrodes 42a and 42b are formed.

Referring to FIG. 6, a third pad layer is formed over the substrate 30 where the first and second epitaxial gate electrodes 42a and 42b are formed. An isolation mask is formed over the third pad layer, and a photolithography process is then performed to pattern the third pad layer and the substrate 30 to a predetermined depth. As a result, first and second isolation trenches are formed while leaving portions of the first and second epitaxial gate electrodes 42a and 42b. An insulation layer is filled into the first and second isolation trenches. The third pad layer is removed, thereby obtaining first and second isolation structures 44a and 44b.

The first isolation trench is a region defined as a portion of the first epitaxial gate electrode 42a which has been removed. And, the first isolation structure 44a, which is formed by the insulation layer filled therein, faces a remaining portion of the first epitaxial gate electrode 42a. Similarly, the second isolation structure 44b is formed to face a remaining portion of the second epitaxial gate electrode 42b. The first and second isolation structures 44a and 44b are formed simultaneously and coupled to each other.

Referring to FIG. 7, the first pad layer 32 is removed from the substrate 30 where the first and second isolation structures 44a and 44b are formed. A gate insulation layer and a polysilicon layer for use in gates are formed over the above resultant structure and patterned to form a patterned gate insulation layer 46a and a gate electrode 46b. The gate insulation layer comprises an oxide-based material. The patterned gate insulation layer 46a and the gate electrode 46b are formed over a region of the substrate 30 between the first epitaxial gate electrode 42a and the second epitaxial gate electrode 42b.

Referring to FIG. 8, an ion implantation process is performed on the above resultant structure illustrated in FIG. 7 to form source and drain regions 48a and 48b in regions adjacent to the first and second isolation structures 44a and 44b. In this connection, the gate electrode 46b is formed to overlap the first epitaxial gate electrode 42a and the second epitaxial gate electrode 42b.

A first surface of the first epitaxial gate electrode 42a and a second surface of the second epitaxial gate electrode 42b that are formed between the source region 48a and the drain region 48b, and a bottom surface of the gate electrode 46b function as a channel region when a certain voltage is applied. Thereafter, a sequential process comprising forming insulation layers, forming of contact holes, filling metallic materials, performing CMP, removing the insulation layers is performed over the source and drain regions 48a and 48b, and the gate electrode 46b, to thereby form contact holes for the source and drain regions 48a and 48b, and the gate electrode 46b.

The first to third surfaces are labeled respectively as M1, M3 and M2 in FIG. 7. As a result, various control methods of driving current can be implemented depending on a method of applying a voltage to each of the first epitaxial gate electrode 42a, the second epitaxial gate electrode 42b and the gate electrode 46b. This effect improves current drivability of the transistor.

On the basis of the exemplary embodiments of the present invention, the first epitaxial gate electrode, the second epitaxial gate electrode and the gate electrode are formed between the source region and the drain region. As a result, various control methods of driving current may be implemented depending on a method of applying a voltage to each of these gates. As a result, the transistor based on the above embodiments of the present invention has an improved current drivability.

While an embodiment of the invention has been shown and described with respect to the preferred embodiments, it will be understood by those skilled in the art that various changes and modifications may be made without departing from the spirit and scope of the invention as defined in the following claims.

What is claimed is:

1. A method of fabricating a transistor of a semiconductor device, the method comprising:
forming first and second trenches for gates in a substrate, wherein the trenches are spaced apart from each other by a predetermined distance;
forming a liner layer on innerwalls of the first and second trenches;
forming first and second epitaxial gate electrodes by performing a selective epitaxial growth on the first and second trenches comprising the liner layers therein;
forming isolation structures in the substrate, wherein the isolation structures are formed to contact the first and second epitaxial gate electrodes, respectively;
forming a gate insulation layer and a gate electrode over a region of the substrate between the first and second epitaxial gate electrodes; and
forming source and drain regions in the substrate disposed in respective edge regions of the gate electrode and overlapping the gate electrode.

2. The method of claim 1, wherein forming the first and second trenches comprises:
sequentially forming a first pad layer and a second pad layer over the substrate;
forming a mask for a trench over the second pad layer;
forming the first and second trenches by performing a photolithography process and an etching process on the second pad layer, the first pad layer and the substrate by using the mask.

3. The method of claim 1, wherein forming the isolation structures comprises:
forming a third pad layer over the substrate comprising the first and second epitaxial gate electrodes formed therein;
forming an isolation mask over the third pad layer;
forming isolation trenches while leaving portions of the first and second epitaxial gate electrodes by performing a photolithography process and an etching process using the isolation mask, wherein the portions nearly facing each other remain; and
filling an insulation layer into the isolation trenches.

4. The method of claim 1, wherein the forming a liner layer comprises forming the liner layer comprising an oxide-based material.

5. The method of claim 1, wherein the forming a gate insulation layer comprises forming the gate insulation layer comprising an oxide-based material.

6. A transistor of a semiconductor device, the transistor comprising:
at least one isolation structure formed in an isolation region of a substrate;
a gate insulation layer formed over an active region of the substrate;
a gate electrode formed over the gate insulation layer;
first and second epitaxial gate electrodes formed in the substrate and spaced apart from each other and comprising the gate electrode disposed on the substrate therebetween, wherein the gate electrode is arranged overlapped with the first epitaxial gate electrode and the second epitaxial gate electrode; and
source and drain regions formed in the substrate disposed in respective edge regions of the gate electrode and overlapping the gate electrode.

7. The transistor of claim 6, wherein the first and second epitaxial gate electrodes are formed by an epitaxial growth in first and second trenches for gates, respectively, the first and second trenches being formed spaced apart from each other by a predetermined distance and comprising a liner layer formed over innerwalls thereof.

8. The transistor of claim 7, wherein the isolation structure faces the first and second epitaxial gate electrodes formed by an epitaxial growth in first and second trenches while leaving portions of the first and second epitaxial gate electrodes, wherein the portions nearly face each other.

9. The method of claim 6, wherein the liner layer comprises an oxide-based material.

10. The method of claim 6, wherein the gate insulation layer comprises an oxide-based material.
